(19) United States
(12) Patent Application Publication
(10) Pub. No.: US 2009/0079201 A1
(43) Pub. Date: Mar. 26, 2009

(54) System and Method for Self-Stowing Information Handling System Lid Latch

(76) Inventors: Eduardo Escamilla, Round Rock, TX (US); Maria C. Schlesener, Austin, TX (US); Jeffrey A. Reed, Austin, TX (US)

Correspondence Address: HAMILTON & TERRILE, LLP, P.O. BOX 203518, AUSTIN, TX, 78720, US

(21) Appl. No.: 11/861,575

(22) Filed: Sep. 26, 2007

(51) Int. Cl. H05K 7/00

(52) U.S. Cl. 292/10

(57) ABSTRACT

A portable information handling system has an automatic latching system that maintains a lid having a display in a desired position relative to a housing, such as a closed position having the lid closed proximate the housing and including a tablet configuration having the display exposed in the closed position. A post automatically extends from the housing into the lid when in the closed position to prevent rotation of the lid. The post automatically retracts into the housing when the lid is in the open position to provide an aesthetically pleasing latch solution for tablet portable information handling systems.

### BACKGROUND OF THE INVENTION

1. Field of the Invention

The present invention relates in general to the field of information handling system convertible lids, and more particularly to a system and method for a self-stowing information handling system lid latch.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Increased performance and decreased size of information handling system components have resulted in a trend towards smaller information handling systems having increased processing power. For example, end users have tended to select portable information handling systems as replacements for desktop systems. Portable information handling systems typically include an integrated display and battery so that the system operates free from external connections for power and peripherals. Typically, the display is integrated into a lid that is rotationally coupled to a portable housing. In a closed position, the lid covers the housing to prevent damage to the display as well a keyboard exposed at the upper portion of the housing. In the closed position, the information handling system is in a portable configuration that allows easy transport. Typically, a latch interacts between the lid and housing to secure the information handling system in the closed position. In order to use the information handling system, the latch is released so that the lid rotates to an open position to expose the display and keyboard.

A modification to the traditional rotational lid and housing has resulted in the development of tablet information handling systems. In a tablet system, the lid rotates approximately 360 degrees so that the system is in a closed configuration with the display and keyboard exposed. Tablet systems typically include a touch screen display that accepts user inputs, such as by handwriting with a stencil on the screen. In addition, tablet systems act as a presentation device since the end user can easily show the display to others. To further improve on the display of information to others, some tablet information handling systems include displays that rotate not only between open and closed positions but also rotate about a central axis running through the middle of the display. For instance, when the lid is open 90 degrees, the end user can rotate the lid about a vertical axis to show the display to individuals sitting across from the end user. Further, once the lid is rotated, the end user can close the lid to form a tablet without rotating the lid a full 360 degrees. One difficulty associated with tablet information handling systems is that rotation about multiple axes requires a latching solution that secures the information handling system in a closed position about each axis. Typically, a latch is used for each axis, however, this requires the end user to activate multiple latches in order to transition to a tablet configuration. Further, conventional latching systems that require multiple end user inputs to transition to a tablet configuration tend to be bulky and are often prominently located along the edge of the housing in a cosmetically unpleasant manner.

### SUMMARY OF THE INVENTION

Therefore a need has arisen for a system and method which secures an information handling system lid along plural axes.

In accordance with the present invention, a system and method are provided which substantially reduce the disadvantages and problems associated with previous methods and systems for securing an information handling system lid to its housing. Posts automatically extend when the lid rotates to a closed position so that rotation about an axis is restricted. The posts automatically retract upon rotation to an open position to remain out of the way of operation of the information handling system.

More specifically, an information handling system has processing components disposed in a housing and a lid rotationally coupled to the housing. The lid rotates about a horizontal axis between open and closed positions and a vertical axis that changes the direction that a display integrated in the lid points. One or more retractable posts disposed in an opening of the housing are biased into the housing opening by springs. As the lid approaches a closed position, a magnet in an opening of the lid draws the posts out of the housing and into the opening of the lid. The posts prevent rotation of the lid about the vertical axis when the lid is in the closed position. Upon movement of the lid from the closed to an open position, the springs bias the posts to retract into the housing to keep the posts out of the way during use of the information handling system. Openings in opposing sides of the lid accept the posts in both a storage configuration with the display against the housing and a tablet configuration with the display exposed.

The present invention provides a number of important technical advantages. One example of an important technical advantage is that an information handling system lid is secured along plural axes with a cosmetically pleasing and simple latch. Retractable posts extend between the lid and housing to prevent rotation of the lid when the lid is closed and retract when the lid is open so that the tablet presents an aesthetically pleasing design. When detent hinges maintain the lid in a closed position, an end user can rotate the lid between a tablet configuration and a closed configuration without actuating any latches. Even where a manual latch is used to maintain the lid in a closed position, a single actuation of the manual latch releases the lid to rotate about multiple axes.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a side view of a portable information handling system with a lid in an open position and operable to rotate about first and second axes;

FIG. 2 depicts a top view of a portable information handling system with a lid in a closed position and operable to rotate about the second axis;

FIG. 3 depicts a side view of a portable information handling system in a closed position and having retractable posts to prevent rotation about the second axis; and

FIGS. 4A and 4B depict retractable posts in an unlatched position and a latched position.

### DETAILED DESCRIPTION

An automated latch secures a portable information handling system in a closed position, including a tablet configuration having a display exposed. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

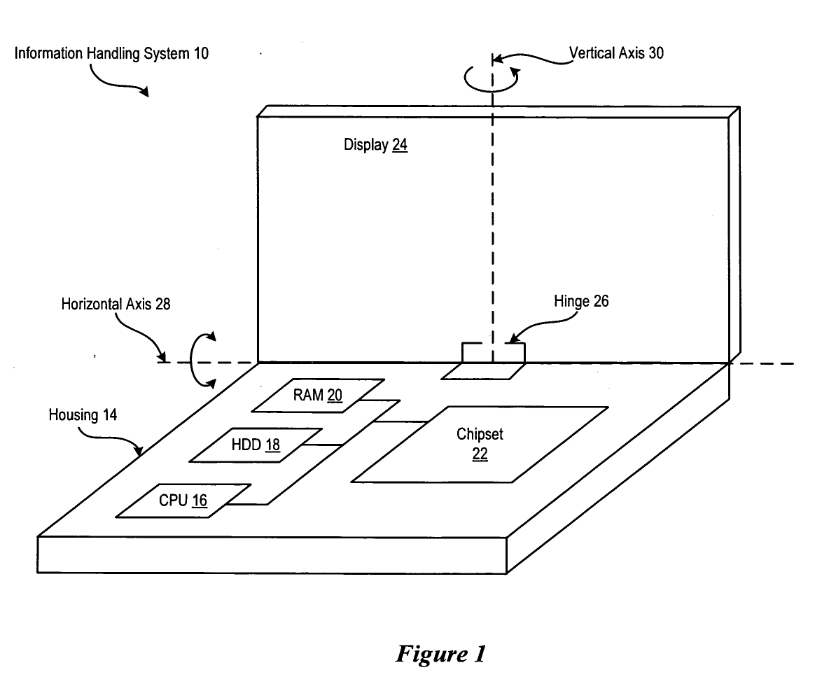

Referring now to FIG. 1, a side view depicts a portable information handling system 10 with a lid 12 in an open position and operable to rotate about first and second axes. Information handling system 10 has plural processing components disposed in a housing 14 that cooperate to process information, such as a CPU 16, a hard disk drive 18, RAM 20 and a chipset 22. Chipset 22 communicates information to a display 24 for presentation to an end user. Display 24 is, for instance, a liquid crystal display (LCD) integrated in lid 12. Lid 12 is rotationally coupled to housing 14 with a hinge 26 that allows rotation about a first horizontal axis 28 and a second vertical axis 30. For example, hinge 26 is a detent hinge that includes a detent mechanism for maintaining lid 12 in predetermined positions. For instance, a detent of hinge 26 is set to maintain lid 12 in a closed position when lid 12 is rotated about horizontal axis 28 to place display 24 proximate housing 14.

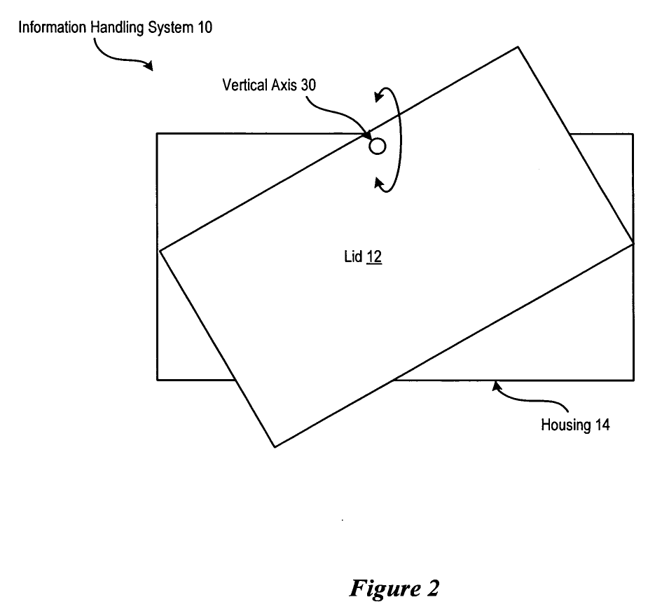

Hinge 26 rotates about vertical axis 30 so that, in the open position, display 24 rotates to face away from the front of housing 14 and the presumed position of an end user. When display 24 is rotated about vertical axis 30 to face the rear of housing 14, rotation about horizontal axis 28 to a closed position will have display 24 facing outwards from housing 14 in a tablet configuration. Hinge 26 includes a detent to maintain lid 12 in the closed position, both for the storage closed position in which the display is not exposed and in the tablet closed position in which the display is exposed. Referring to FIG. 2, a top view depicts a portable information handling system 10 with a lid in a closed position and operable to rotate about the vertical second axis 30. In the closed position depicted by FIG. 2, lid 12 has display 24 exposed in the tablet configuration and not exposed in the storage configuration. Rotation of lid 12 relative to housing 14 is generally not desirable. In order to prevent rotation about axis 30, a latch is engaged when lid 12 and housing 14 are aligned. Automatic engagement of the latch in either the storage or the tablet configuration to prevent rotation about axis 30 allows end users to select the storage or tablet configuration without a need for manual manipulation of a latch switch.

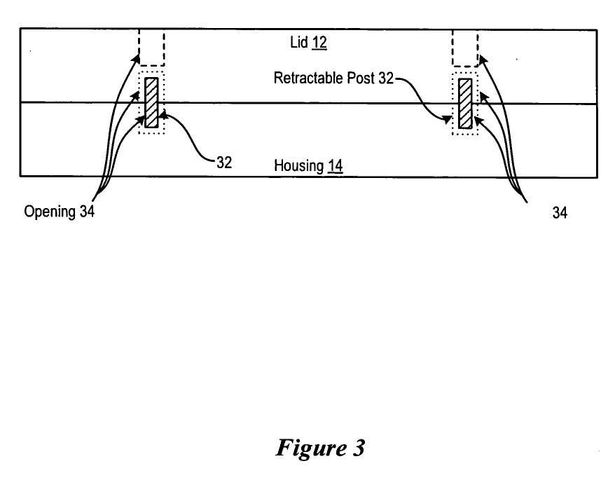

Referring now to FIG. 3, a side view depicts a portable information handling system 10 in a closed position and having retractable posts 32 to prevent rotation about the vertical second axis. Posts 32 are stored out of sight in openings 34 of housing 14 when lid 12 is in an open position. However, as lid 12 is rotated to a closed position, an opening 34 in lid 12 aligns with the opening 34 in housing 14 and post 32 drawn from within housing 14 and into lid 12. The insertion of post 32 into opening 34 prevents rotation of lid 12 about the vertical axis 30. In alternative embodiments, post 32 might instead store in lid 12 and extend into housing 14. However, placing posts 32 in housing 14 provides the advantage of dual use of a post 32 for maintaining the lid 12 in the closed position for both the storage and tablet configurations. Openings 34 on opposing sides of lid 12 are each aligned to accept the same post 32. In the storage configuration, openings 34 proximate to the display side of lid 12 accept post 32. In the tablet configuration, openings 34 on the side of lid 12 opposite the display accept post 32 so that the display is exposed with lid 12 closed against housing 14.

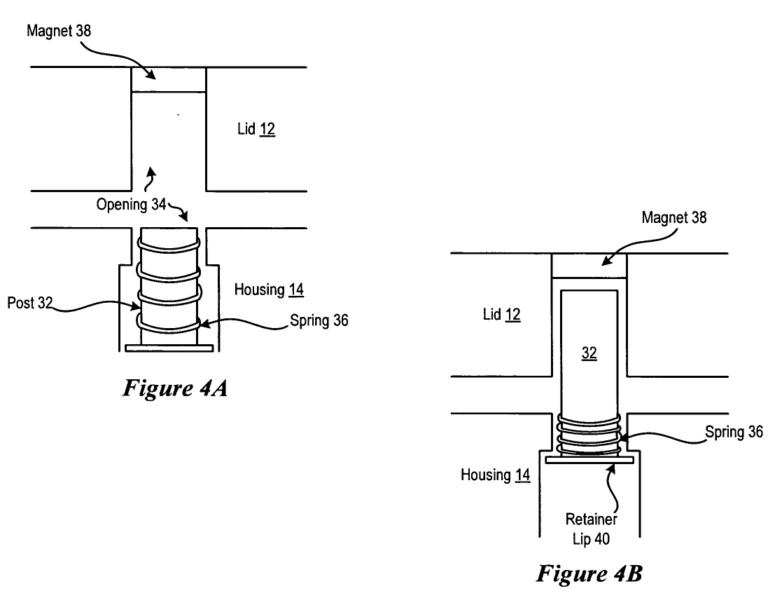

Referring now to FIGS. 4A and 4B, retractable posts are depicted in an unlatched position and a latched position. In the unlatched position of FIG. 4A, post 32 is biased into opening 34 of housing 14 by a spring 36. As lid 12 approaches housing 14, a magnet 38 builds a magnetic attraction with a ferrous material of post 32 to overcome the bias of spring 36 and draw post 32 into the opening 34 of lid 12, as depicted by FIG. 4B. In alternative embodiments, a magnet might instead be associated with post 32 to attract to ferrous material in lid 12, or a magnet might be associated with both post 32 and lid 12. As post 32 extends from housing 14 into lid 12, a retaining lip 40 limits the extension to prevent the withdrawal of post 32 from the opening 34 within housing 14. Thus, post 32 automatically extends when lid 12 is in a closed position to prevent rotation about the vertical axis and retracts when lid 12 is in the open position to limit any interference caused by the latch with the use of the information handling system. Automatic extension and retraction allows an end user to open and close the lid without manual activation of a latch associated with the vertical axis.

Although the present invention has been described in detail, it should be understood that various changes, substitutions and alterations can be made hereto without departing from the spirit and scope of the invention as defined by the appended claims.

What is claimed is:

1. An information handling system comprising:
a housing;
processing components disposed in the housing and operable to process information;
a lid coupled to the housing and operable to rotate about a first axis between open and closed positions and a second axes perpendicular to the first axis;
a display integrated in the lid, the display interfaced with the processing components and operable to present the information as visual images; and
a latch operable to prevent rotation about the second axis with the lid in the closed position, the latch automatically retracting upon rotation of the lid from the closed position.

2. The information handling system of claim 1 wherein the latch comprises a post that extends in the closed position and retracts in the open position.

3. The information handling system of claim 2 wherein the post resides in the housing, the post aligned to enter an opening formed in the lid on a side proximate the display.

4. The information handling system of claim 3 wherein the post is further aligned to enter an opening formed in the lid on a side opposite the display to prevent rotation in the tablet position.

5. The information handling system of claim 1 wherein the latch comprises:
a post disposed in the housing;
a spring coupled to the post, the spring operable to bias the post to retract into the housing; and
a magnet disposed in an opening of the lid, the magnet operable to attract the post from the housing into the lid with the lid in the closed position.

6. The information handling system of claim 5 further comprising detent hinges coupled to the housing and lid, the detent hinges operable to maintain the lid position about the first axis.

7. A method for maintaining the position of an information handling system lid relative to a housing, the method comprising:
placing the lid in a closed position relative to the housing;
aligning an opening associated with one of the lid or housing and a post associated with the other of the lid or housing; and
automatically drawing the post to extend into the opening.

8. The method of claim 7 wherein automatically drawing further comprises applying a magnetic force between the post and the opening.

9. The method of claim 7 wherein aligning an opening further comprises aligning an opening formed in the lid proximate a display with a post disposed in the housing.

10. The method of claim 7 wherein aligning an opening further comprises aligning an opening formed in the lid opposite the display with a post disposed in the housing so that the closed position is a tablet configuration.

11. The method of claim 7 further comprising:
rotating the lid from the closed position to an open position; and
automatically retracting the post into the one of the housing or lid.

12. The method of claim 11 wherein automatically retracting further comprises biasing the post into the one of the housing or lid with a spring.

13. The method of claim 7 further comprising maintaining the closed position of the lid and housing with a detent hinge coupled to the lid and housing.

14. A system for maintaining the position of an information handling system lid relative to a housing, the system comprising:
a post sized to extend from a first opening associated with one of the lid or housing into a second opening associated with the other of the lid or housing;
a biasing mechanism associated with the post and operable to bias the post into the first opening; and
an extending mechanism associated with the post and operable to extend the post from the first opening to the second opening when the lid closes to a position proximate the housing.

15. The system of claim 14 wherein the biasing mechanism comprises a spring coupled to the post to bias the post into the first opening.

16. The system of claim 14 wherein the extending mechanism comprises a magnet integrated in the post and a ferrous metal integrated in the second opening, the magnet attracted to the ferrous metal to draw the post into the second opening.

17. The system of claim 14 wherein the extending mechanism comprises a magnet integrated in the second opening and a ferrous metal integrated in the post, the magnet attracted to the ferrous metal to draw the post into the second opening.

18. The system of claim 14 wherein the first opening is formed in the housing, the biasing mechanism biasing the post into the housing.

19. The system of claim 18 wherein the second opening is formed in the lid proximate a display so that the post extends into the second opening when the lid closes the display against the housing.

20. The system of claim 18 wherein the second opening is formed in the lid opposite a display so that the post extends into the second opening when the lid closes against the housing to expose the display in a tablet configuration.
